(19) United States
(12) Patent Application Publication
(10) Pub. No.: US 2014/0167571 A1
(43) Pub. Date: Jun. 19, 2014

(54) PIEZOELECTRIC TRANSFORMER WITH HIGH EFFECTIVE ELECTROMECHANICAL COUPLING FACTORS

(71) Applicant: Kaspar Sinding Meyer, Copenhagen N (DK)

(72) Inventor: Kaspar Sinding Meyer, Copenhagen N (DK)

(73) Assignee: Noliac A/S, Kvistgaard (DK)

(21) Appl. No.: 14/237,432

(22) PCT Filed: Aug. 3, 2012
(86) PCT No.: PCT/EP2012/065261

§ 371 Date: Mar. 5, 2014

Related U.S. Application Data
(60) Provisional application No. 61/521,635, filed on Aug. 9, 2011.

(30) Foreign Application Priority Data
Aug. 9, 2011 (EP) 11176929.5

(51) Int. Cl. H01L 41/107

(52) U.S. Cl. CPC H01L 41/107
USPC 310/366

(57) ABSTRACT

The present invention relates to a piezoelectric transformer comprising an elongate piezoelectric ceramic body adapted to operate in fundamental thickness mode. The elongate piezoelectric ceramic body comprises a central input or primary section coupled to adjacently arranged first and second output sections. High power conversion efficiency and zero-voltage switching capability is achieved by providing a primary side effective electromechanical coupling factor k_{eff}_{_{—}}_{P}, which is larger than a secondary side electromechanical coupling factor, k_{eff}_{_{—}}_{S}.

The present invention relates to a piezoelectric transformer comprising an elongate piezoelectric ceramic body adapted to operate in fundamental thickness mode. The elongate piezoelectric ceramic body comprises a central input or primary section coupled to adjacently arranged first and second output sections. High power conversion efficiency and zero-voltage switching capability are achieved by providing a primary side effective electromechanical coupling factor, k_{eff}_{_{—}}_{P}, which is larger than a secondary side effective electromechanical coupling factor, k_{eff}_{_{—}}_{S}.

### BACKGROUND OF THE INVENTION

Piezoelectric transformers are known alternatives to magnetics in power converters such as AC-AC step-up or step-down converters, DC-DC step-up or step-down converters or AC-DC step-up or step-down converters. Piezoelectric transformers have several advantages in comparison to their magnetic counterparts such as low level of conducted and radiated EMI because the power conversion is based on the piezoelectric effect. The size and electrical conversion efficiency of piezoelectric transformers are of outmost importance in numerous applications just as the case with magnetics based power converters. A piezoelectric transformer comprises a piezoceramic material shaped as an acoustic resonator with a fundamental resonance frequency typically situated well above the audible band. The piezoceramic material is shaped as piezoelectric body which can exhibit a dense storage of kinetic energy. A piezoelectric transformer is inherently capacitive in nature which means that an electrical interface to switch mode operating power transistors of an input driver advantageously can be made with certain precautions to obtain so-called zero-voltage switching.

The present invention is based on novel insights about physics of piezoelectric transformers as regards their zero-voltage switching factors (denoted “ZVS factor”). The present inventor has demonstrated that by configuring or designing the piezoelectric transformer such that it is easier to supply energy to the transformer than extract energy therefrom the piezoelectric transformer exhibits inductive input impedance across a certain or predetermined frequency band or range. In other words, the piezoelectric transformer can be forced to display a pseudo inductive behavior. In mathematical terms this constraint can be formulated by effective and straightforward mathematical expressions coupling the desired inductive behaviour to a relationship between the primary side effective electromechanical coupling factor, k_{eff}_{_{—}}_{P}, and the secondary side effective electromechanical coupling factor, k_{eff}_{_{—}}_{S}, of the piezoelectric transformer. Furthermore, the primary and secondary side effective electromechanical coupling factors of the piezoelectric transformer can be related to its ZVS factor which indicates an inductiveness of the piezoelectric transformer. The ZVS factor indicates how effective a given piezoelectric transformer design is to enable zero-voltage-switching or soft-switching of an input driver, such as a MOS or IGBT transistor based driver, electrically coupled to the input section of the piezoelectric transformer. The realization of such zero-voltage-switching in the driver is highly advantageous because it facilitates high power conversion efficiency of a complete power converter based on the piezoelectric transformer and its associated driver. The inventor's insight has enabled the design of a novel class of elongate depth mode piezoelectric transformers with topologies which at the same time exhibit both high ZVS factor and high power conversion efficiency as explained in further detail below. In essence, this property ensures a combined optimization of electrical switching losses associated with the input driver and conversion losses of the piezoelectric transformer.

The intrinsic pseudo inductive or inductive behavior of the present class of elongate piezoelectric transformers allows a power converter based thereon to operate without the ordinary external series inductor and still maintain zero voltage switching operation in the input driver/half-bridge portion of the power converter. The ability of the power converter to operate with good power conversion efficiency without the ordinary external series inductor entails several significant advantages such as smaller dimensions, a freely selectable height dimension, a decrease of inductive losses caused by reactive coil currents etc. In addition, the lack of the ordinary external series or parallel inductor leads to a lower level of conducted and radiated EMI because of the elimination of external magnetic components in the power converter.

WO 2010/097407 describes a piezoelectric transformer for semiconductor based light sources. The employed piezoelectric transformers are based on ring-shaped piezoelectric bodies with ZVS factors of 100% and 120%.

US 2010/0328969 describes an electronic power converter comprising a piezoelectric transformer driven by an input voltage signal with a burst frequency and a substantially constant excitation frequency. A ring shaped thickness mode piezoelectric transformer with a ZVS factor of about 100% or 120% is disclosed.

The paper “Parameterized Analysis of Zero Voltage Switching in Resonant Converters for Optimal Electrode Layout of Piezoelectric” ISBN: 978-1-4244-1667-7 discloses the design of ring shaped PT operating in thickness mode.

U.S. Pat. No. 6,215,227 discloses a rectangular thickness mode piezoelectric transformer with an input section arranged in-between a pair of adjoining output sections. Opposing end faces of the output sections have end-masses attached thereto to increase the thickness of the piezoelectric transformer and decrease its resonant frequency.

U.S. Pat. No. 5,440,195 discloses a rectangular ceramic piezoelectric transformer with an output section polarized in lengthwise direction arranged in-between a pair of adjoining input or driving sections. The driving sections have multi-layered electrode structures and are operating in planar mode.

### SUMMARY OF THE INVENTION

A first aspect of the invention relates to a piezoelectric transformer comprising:
an elongate piezoelectric ceramic body adapted to operate in fundamental thickness mode. The elongate piezoelectric ceramic body comprises a central input section polarized in a direction substantially parallel to a longitudinal body axis of the elongate piezoelectric ceramic body. The input section comprises a first and a second input electrode for applying an electrical field to the central input section along its polarization direction. A first output section is polarized in a direction substantially parallel to the longitudinal body axis and the first output section is arranged in abutment to the central input section at a first connection surface. The first output section further comprises a first output electrode. A second output section is polarized in a direction substantially parallel to the longitudinal body axis. The second output section being arranged in abutment to the central input section at a second connection surface, arranged oppositely to the first connection surface. The second output section further comprises a second output electrode; In addition, a primary side effective electromechanical coupling factor, k_{eff}_{_{—}}_{P}, is larger than a secondary side effective electromechanical coupling factor, k_{eff}_{_{—}}_{S}, in which:

$$\begin{matrix}{k}_{eff\_P} = \sqrt{1 - \frac{{f}_{res\_p}^{2}}{{f}_{anti - res\_p}^{2}}} & ( 1 ) \\ {k}_{eff\_S} = \sqrt{1 - \frac{{f}_{res\_s}^{2}}{{f}_{anti - res\_s}^{2}}} & ( 2 )\end{matrix}$$

fᵣₑₛ_{_{—}}ₚ=resonance frequency and frequency of a minimum magnitude of an impedance function at the input electrodes of the piezoelectric transformer with shorted output electrodes,
fₐₙₜᵢ₋ᵣₑₛ_{_{—}}ₚ=anti-resonance frequency and frequency of a maximum magnitude of the impedance function at the input electrodes of the piezoelectric transformer with shorted output electrodes,
fᵣₑₛ_{_{—}}ₛ=resonance frequency and frequency of a minimum magnitude of the impedance function at the output electrodes of the piezoelectric transformer with shorted input electrodes,
fₐₙₜᵢ₋ᵣₑₛ_{_{—}}ₛ=anti-resonance frequency and frequency of a maximum magnitude of the impedance function at the output electrodes of the piezoelectric transformer with shorted input electrodes.

The cross-section of the elongate piezoelectric ceramic body may take any arbitrary shape or profile of which the following are exemplary shapes out of numerous different shapes such as a rectangular, circular, or elliptical or simple n-gon polygon with 5, 6, 7 or more sides. The term “elongate” means that a length of the elongate piezoelectric ceramic body is larger than any other dimension thereof such as a thickness, width or diameter of the elongate piezoelectric ceramic body. Furthermore, according to a preferred embodiment of the invention, the length of the elongate piezoelectric ceramic body is at least two times larger than any other dimension thereof to create a rod-shaped form. The latter constraint ensures that a half-wave length resonance frequency is excited when an input signal of appropriate frequency is applied between the first and second input electrodes such that the elongate piezoelectric ceramic body operates in the fundamental thickness mode to avoid or at least suppress influence from unwanted spurious modes. This mode is often designated as k₃₃-k₃₃-k₃₃-mode or simply k₃₃₃-mode.

The first and second secondary or output sections can either be polarized or configured to operate parallelly or to operate separately where the first and second output electrodes are coupled to separate electrical loads. One of the first and second input electrodes may comprise common electrode shared between the central input section and the first and/or second output section such that the common electrode serves as a ground or negative voltage reference for the piezoelectric transformer.

In accordance with the present invention, the central input or primary section of the elongate piezoelectric ceramic body is arranged in-between the first and second output sections because this topology or design provides a large mass for the input section to “push” against compared to each of the first and second output sections. This feature is therefore particularly helpful in making the primary side effective electromechanical coupling factor, k_{eff}_{_{—}}_{P}, markedly larger than the secondary side effective electromechanical coupling factor, k_{eff}_{_{—}}_{S} so as to improve the ZVS factor of the piezoelectric transformer.

The elongate piezoelectric ceramic body preferably comprises a piezoelectric ceramics material such as a hard doped Lead Zirconate Titanate e.g. Pz26 available from the supplier Ferroperm Piezoceramics NS. Other suitable materials include hard doped piezoceramic materials like NCE40, NCE41 and NCE46 available from the supplier Noliac NS, which like the Pz26 material, all exhibit large k₃₃ electromechanical coupling factors such coupling factors above 0.65. The Pz26 piezoelectric ceramics material has a typical value of k₃₃ in the thickness direction, i.e. parallel to the direction of polarization, of 0.65 or 65%, compared to a k₃₁ factor of 0.33 or 33% in a direction perpendicular to the direction of polarization. Another embodiment of the elongate piezoelectric ceramic body utilizes the hard doped piezoceramic material NCE46 which has a k₃₃ coupling factor (in the thickness direction, i.e. parallel to the direction of polarization) of 0.68 while the corresponding k₃₁ coupling factor is 0.33 (in a direction perpendicular to the direction of polarization). Furthermore, the respective values of the primary and secondary side effective electromechanical coupling factors k_{eff}_{_{—}}_{P}, and k_{eff}_{_{—}}_{S}, respectively, can be further increased or optimized by selecting a hard doped piezoceramic material which, in addition to the above k₃₃ coupling factor values, possesses a large mechanical quality factor Qₘ, preferably a value of Qₘ on 1000 or larger.

Hence, the primary side and secondary side effective electromechanical coupling factors can be made large due to the exploitation of the k₃₃ electromechanical coupiing factors, and optionally large mechanical quality factors Qₘ, of the input and output sections of the PT. In preferred embodiments, the primary side effective electromechanical coupling factor k_{eff}_{_{—}}_{P} is larger than 0.30 or 30%, or larger than 0.35 or 35%, preferably larger than 0.40 or 40%, even more preferably larger than 0.50 or 50% or 0.60 or 60%. The large primary side effective electromechanical coupling factor can for example be reached by selection of suitable piezoelectric ceramics material with large k₃₃ electromechanical coupling factor, as outlined above, and selecting an appropriate volume of the central input section as described below in further detail in connection with FIGS. 1-3.

Generally, electromechanical coupling factors such as k₃₃ and k₃₁ of a piezoelectric ceramic material are non-dimensional coefficients which are useful for describing a particular piezoelectric ceramic material under a particular stress and electrical field configuration for conversion of stored energy to mechanical or electrical work. The electromechanical coupling factors consist of particular combinations of piezoelectric, dielectric, and elastic coefficients. Since the coupling factors are dimensionless, they serve as a useful comparison between different piezoelectric materials independent of the specific values of permittivity or compliance, both of which may vary widely. The effective electromechanical coupling factors are defined for measurements of frequencies near the resonance and the anti-resonance of a piezoelectric ceramic body. As such the effective electromechanical coupling factors are related to the quasi-static coupling factors of a given material in addition to the physical shape of the object in question.

In another embodiment of the piezoelectric transformer the primary side effective electromechanical coupling factor k_{eff}_{_{—}}_{P} is at least 10% larger, such as between 12% and 80% larger, than the secondary side effective electromechanical coupling factor k_{eff}_{_{—}}_{S} to enhance the ZVS capabilities and versatility of the transformer by taking into account real-world production and temperature variations in both characteristics of the piezoelectric transformer and characteristics of the input driver coupled to the central input section of the piezoelectric transformer. These real-word characteristics include e.g. variations in parasitic capacitances of driver transistors and transformer input capacitance variations.

According to a preferred embodiment of the invention, the elongate piezoelectric ceramic body is shaped and sized to provide a ZVS factor larger than 1.0 or 100%, preferably larger than 1.2 or 120%, such as larger than 1.5 or 150% or 2.0 or 200%; in which the ZVS factor is determined at a matched load condition as:

$$Z V S = \frac{{k}_{eff\_S}^{- 2} - 1}{{k}_{eff\_P}^{- 2} - 1} 0.882 \qquad ( 3 )$$

Even though a ZVS factor of 1.0 or 100% in theory may suffice to obtain the desired inductive behaviour of the piezoelectric transformer, practical considerations suggest that using the above-mentioned larger values is often advantageous. One reason is that a piezoelectric transformer with a ZVS factor of about 100% will solely exhibit the desired inductive behaviour in an extremely narrow frequency band or range such that it may be difficult to properly adjust the excitation frequency of the AC input signal.

In one advantageous embodiment, the ZVS factor is larger than 125% and a volume of the central input section occupies less than 50%, and more preferably less than 40%, of a volume of the elongate piezoelectric ceramic body. The short length of the central input section while maintaining a large ZVS factor leads to a half-wave length resonance frequency, which is utilised for operation in the fundamental thickness mode, situated at a high frequency because of the accompanying short length of the entire elongate piezoelectric ceramic body. A high frequency value of the half-wave length resonance frequency may lead to a higher power density in the piezoelectric transformer.

The simultaneous provision of a high ZVS factor and the low volumetric occupation of the central input section, relative to the entire elongate piezoelectric ceramic body, have in part been achieved by using the above-mentioned k₃₃ electromechanical coupling factor of the piezoelectric ceramics of the central input section of the elongate piezoelectric ceramic body. By exploiting the k₃₃ coupling factor of the piezoelectric ceramic material, a large effective electromechanical coupling factor is achieved to provide a piezoelectric transformer with compact dimensions without compromising the ZVS capabilities of the piezoelectric transformer.

As mentioned above, the length of the elongate piezoelectric ceramic body is preferably at least two times larger than any other dimension thereof because this constraint ensures the half-wave length resonance frequency is excited by the AC input voltage or signal during operation. This is important to maximize conversion efficiency. The elongate piezoelectric ceramic body may be shaped as a substantially rectangular “slab” having a length that is two or more times larger than its width. The width is furthermore preferably two or more times larger than a thickness of the body.

According to yet another preferred embodiment of the present piezoelectric transformer, the elongate piezoelectric ceramic body is formed as a single unitarily machined body of anisotropic piezoelectric compound without any junctions or joints at the first and second connection surfaces. After sintering of the elongate piezoelectric ceramic body, the resulting body structure is designated a co-fired structure. This unitarily body structure of the elongate piezoelectric ceramic body is often designated a ‘bulk component’. The unitary or bulk structure without junctions may lead to an piezoelectric ceramic body with high mechanical strength due to the lack of mechanical attachment means or compounds such as glue, welding or soldering agents between the central input section and the output sections at the first and second connection surfaces.

The unitary structure may be provided by machining or forming the elongate piezoelectric ceramic body by stacking a plurality of individual thin ceramic layers build uniformly lengthwise along the longitudinal body axis. In this manner, the elongate piezoelectric ceramic body is built layer by layer in the thickness direction thereof. Each of the thin ceramic layers may have a thickness between 10 and 200 μm such as between 20 and 50 μm after sintering. Each of the first and second input electrodes may be printed on each of the thin layers in transversal direction to the longitudinal body axis at appropriate locations in the input section. In this structure or build-up, each of the first and second input electrodes is formed as vertical stack of individual electric conductive fingers with intervening layers of piezoelectric compound. This structure of the elongate piezoelectric ceramic body is often designated “interdigital” construction, “33_{IDE}3” build-up or IDE build-up and may serve to emulate a true 333 thickness structure or build-up of the elongate piezoelectric ceramic body. Each input electrode may comprise between 20 and 80 individual electrically conductive fingers depending on the thickness of the elongate piezoelectric ceramic body, the thickness of the individual thin ceramic layers and other factors. The IDE structure is normally simpler to manufacture in current production methods than a true 333 thickness structure which on the other hand has a potential to provide higher power conversion efficiency and/or power density because the primary side effective electromechanical coupling factor, k_{eff}_{_{—}}_{P} is not degraded by an inactive area/volume of piezoceramic material caught between the individual electric conductive fingers of the IDE electrodes.

In another embodiment the elongate piezoelectric ceramic body is formed by between 2 and 5 separate piezoelectric ceramics structures. The elongate piezoelectric ceramic body may be fabricated from two, three or more separate ceramics structures that are firmly attached to each other in lengthwise direction by gluing, welding or soldering. The separate ceramics structures may be bonded together by a Low Temperature Co-firing Ceramic (LTCC) material.

According one such embodiment, the central input section of the elongate piezoelectric ceramic body is fabricated as a single unitary of bulk component, preferably including input electrodes such as the above-discussed IDE input electrodes, and the first and second output sections fabricated as separate bulk components or parts as well. The first and second input electrodes preferably comprise a first vertically extending input electrode and a second vertically extending input electrode, respectively. The first and second vertically extending input electrodes being separated by an intermediate section of piezoelectric material in direction of the longitudinal body axis. A distance between first and second vertically extending input electrodes sets an electric field strength applied to the input section for a given input voltage or primary side voltage. The distance, along the longitudinal body axis, between first and second vertically extending input electrodes may vary depending on requirements of a particular application and the respective dimensions of the input section and first and second output sections. In a number of useful embodiments, the distance lies between 100 and 1000 μm such as between 200 and 500 μm. The distance is measured from center to center of the first and second vertically extending input electrodes in view of their significant lengthwise extension (i.e. the electrode width) in some embodiments of the present invention.

Another embodiment, wherein the elongate piezoelectric ceramic body also comprises three separate, but mutually bonded ceramics structures, comprises a central input section fabricated as a true 333 thickness structure manufactured by stacking or adding thin ceramics layers in a lengthwise direction of the central input section. The first and second output sections are preferably fabricated as separate bulk or unitary components. Very large ZVS factors for example about 170% have also been achieved by this embodiment as evidenced by the below outlined experimental results.

In another embodiment of the invention, the first vertically extending input electrode comprises a plurality of first electrode members distributed along the longitudinal body axis and separated by intermediate sections of piezoelectric material. Likewise, the second vertically extending input electrode comprises a plurality of second electrode members distributed along the longitudinal body axis and separated by intermediate sections of piezoelectric material. The number of first electrode members is preferably between 2 and 8 and the number of first electrode members is preferably between 2 and 8. In one advantageous variant of this embodiment, the first and second electrode members are arranged in an interdigitated or braided pattern along the longitudinal body axis such that pairs of first and second electrode members are facing each other separated by the intermediate sections of piezoelectric material. This embodiment makes it possible to adjust the electric field strength applied to the central input section for a given input voltage by selecting the number of pairs of the first and second electrode members distributed across the input section.

As mentioned above in connection with the interdigital construction or 33_{IDE}3 build-up of the elongate piezoelectric ceramic body, the first vertically extending input electrode, or each of the first electrode members, may comprise respective set(s) of electrically conductive horizontal fingers aligned vertically above each other and separated by intervening layers of the piezoelectric material. Likewise, the second vertically extending input electrode, or each of the second electrode members, may comprise respective set(s) of electrically conductive horizontal fingers aligned vertically above each other and separated by intervening layers of the piezoelectric material.

According to a preferred embodiment of the invention, the first vertically extending input electrode, or each of the first electrode members, is/are electrically connected to a first electrically conductive layer arranged at a first exterior surface of the elongate piezoelectric ceramic body. In addition, the second vertically extending input electrode, or each of the second electrode members, is/are electrically connected to a second electrically conductive layer arranged at a second exterior surface of the elongate piezoelectric ceramic body. The first and second electrically conductive layers may serve as first and second externally accessible input terminals for providing electrical connection to an input voltage source delivering the AC input voltage. layer, on an end surface of the first output section and the second output electr The respective distances, along the longitudinal body axis, between individual electrode members of the first and second vertically extending input electrodes may be set to about the double of the distance between the latter to facilitate the previously mentioned interdigitated pattern. The distances between the individual electrode members of the first and second vertically extending input electrodes may therefore lie between 200 μm and 2 mm, more preferably between 400 μm and 1 mm.

According to yet another embodiment of the invention, the first output electrode is arranged, e.g. by printing or deposition of a metallic ode arranged, e.g. by printing or deposition of a metallic layer, on an end surface of the second output section. In addition, a length of each of the first and second output electrodes is less than 1 mm, preferably less than 100 μm, even more preferably less than 20 μm. The length is measured along the longitudinal body axis. In this embodiment, the respective lengths of the first and second output electrodes will typically be much less than the respective lengths of the first and second output sections to ensure that large or high values of the primary side and secondary side effective electromechanical coupling factors are achieved. The small length, within the above-mentioned constraints, of each of the first and second output electrodes ensures that the desired difference between the primary side effective electromechanical coupling factor, k_{eff}_{_{—}}_{P}, and the secondary side effective electromechanical coupling factor, k_{eff}_{_{—}}_{S} is maintained so as to provide the desired inductive behaviour of the piezoelectric transformer.

According to another embodiment of the invention, where the first output electrode is arranged on an end surface of the first output section and the second output electrode arranged on an end surface of the second output section, the length of each of the first and second output electrodes is significantly less than the length of the first and second output sections, such as less than 50%, or preferably less than 10%, or even more preferably less than 1%, of the length.

A second aspect of the invention relates to a resonant piezoelectric power converter comprising a piezoelectric transformer according to any of the above-described embodiments. The resonant piezoelectric power converter comprises a transistor driver having an output electrically coupled to the first and second input electrodes of the input section of the piezoelectric transformer. The transistor driver is furthermore adapted to applying an input AC voltage of predetermined amplitude and frequency characteristics to the first and at second input electrodes. A load impedance is electrically coupled to the first and second output sections of the piezoelectric transformer for receipt of a transformed AC voltage. The transistor driver may comprise a half-bridge or full bridge circuit comprising cascaded e.g. NMOS or IGBT transistors. The full bridge circuit comprises a pair of complementary outputs coupled to respective ones of the first and second input electrodes. In a preferred embodiment of the resonant piezoelectric power converter an excitation frequency of the input AC voltage is situated between 5 and 10% above a fundamental resonance frequency, i.e. the half-wave resonance, of the elongate piezoelectric ceramic body. This range of excitation frequencies allows the piezoelectric transformer to be operated in a frequency range wherein the transformer displays the desired inductive behaviour such that an external inductor can be avoided as discussed above in detail.

### BRIEF DESCRIPTION OF THE DRAWINGS

A preferred embodiment of the invention will be described in more detail in connection with the appended drawings, in which:

FIGS. 1a), 1b) and 1c) illustrate schematically a perspective view, a horizontal cross-sectional view and a vertical cross-sectional view, respectively, of a piezoelectric transformer in accordance with a first embodiment of the invention,

FIG. 2 shows a measured input/primary side impedance curve and a measured output/secondary side impedance curve of an experimental piezoelectric transformer in accordance with a first version of the first embodiment of the invention,

FIG. 3 shows a measured input/primary side impedance curves and a measured output/secondary side impedance curve of an experimental piezoelectric transformer in accordance with a second version of the first embodiment of the invention; and

FIG. 4) is a schematic top side view of a multi-piece piezoelectric transformer in accordance with a third embodiment of the invention.

### DETAILED DESCRIPTION OF PREFERRED EMBODIMENTS

The embodiments of the present piezoelectric transformer described in detail below are particularly well-suited for power converters providing AC voltage amplification or step-up. The AC voltage amplification may for example be exploited to generate output voltages above 2000 Volt or event 6000 Volt. Such high AC voltages are very useful for driving for example dielectric electroactive polymer actuators. However, the skilled person will understand that piezoelectric transformers in accordance with the present invention are highly useful for other types of applications both step-up and step down voltage converting applications.

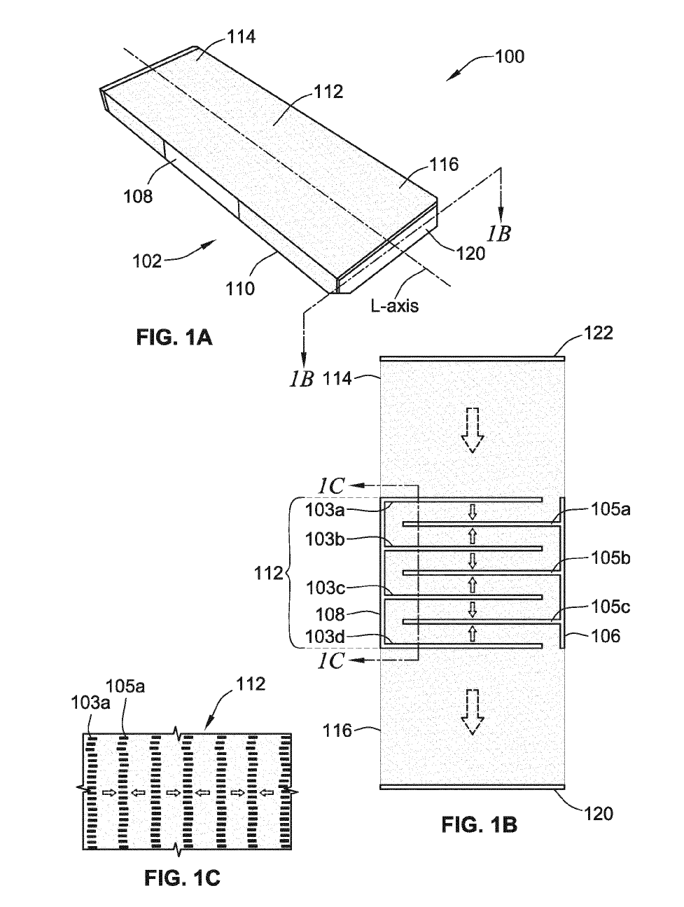

FIG. 1a) is a perspective view of a piezoelectric transformer 100 comprising an elongate piezoelectric ceramic body 102 adapted to operate in fundamental thickness mode. Thickness mode operation is achieved by polarizing a central input section or primary section 112 in a direction substantially parallel to a longitudinal body axis, L-axis, of the elongate piezoelectric ceramic body 102 as indicated by a set of electrical field arrows inside the input section 112 (refer to FIG. 1 b)). The input section 112 comprises a first vertical input electrode comprising four individual first electrode members 103a-d. The four individual first electrode members 103a-d are terminated electrically in an externally accessible electrically conductive layer 108 arranged at a proximate exterior surface 110 of the elongate piezoelectric ceramic body 102. A second input electrode 105 is terminated in another externally accessible electrically conductive layer 106 arranged at an opposing exterior surface to the proximate exterior surface 110. By application of an AC input voltage between the electrically conductive layers 108, 106 coupled to the first and second input electrodes, respectively, electrical fields are applied to the central input section 112 along its polarization direction as described in further detail below. The elongate piezoelectric ceramic body 102 further comprises a first output section 116 polarized in a direction substantially parallel to a longitudinal body axis, L-axis, of the body in a direction indicated by the solid arrow therein. The first output section 116 is arranged in abutment to the central input section 112 at a first connection surface situated at the electrode member 103d extending width wise across the elongate piezoelectric ceramic body 102. In the present embodiment, the first connection surface is formed as a continuous layer of piezoelectric material joining or coupling the first output section 116 to the central input section 112. The same type of continuous transition is provided between the second output section 114 and the central input section 112 at an opposite side of the input section 112 relative to the first connection surface. In this manner, the elongate piezoelectric ceramic body 102 is formed as a unitary body without bonding or attachment means at the first and second connection surfaces. The second output section 114 is also polarized in a direction substantially parallel to the longitudinal body axis, L-axis, as indicated by the solid arrow therein.

The first output section 116 comprises a first output electrode 120 arranged at an end surface thereof. Likewise, the second output section 114 comprises a second output electrode 122 deposited on an end surface of the second output section arranged oppositely lengthwise to the end surface carrying the first output electrode 120. Each of the first and second output electrodes 120, 122, respectively, preferably comprises a thin layer of metallic material or other electrically conductive material. Each of the first and second output electrodes 120, 122, respectively, may be fastened or arranged on the end surface of the output section in question by printing techniques or similar methods of depositing metallic material on ceramic surfaces. Alternatively, the first and second output electrodes 120, 122 may be fastened to the end surface in question by welding, gluing or soldering a thin slab of electrode material to the end surface. In both situations, a length (along the L-axis) of each of the first and second output electrodes 120, 122, respectively, may be less than 1 mm, preferably less than 100 μm, or even more preferably less than 20 μm.

As illustrated by the horizontal cross-sectional view depicted on FIG. 1 b) taken along line B-B, the first vertical input electrode 103 of the central input section 112 comprises a set of four electrode members 103a-d. As illustrated, individual electrode members are separated by intermediate sections of piezoelectric material in direction of the longitudinal body axis, the L-axis. The second input electrode 105 likewise comprises a set of three vertical electrode members 105a-c separated by intermediate sections of piezoelectric material in direction of the longitudinal body axis, L-axis. As previously explained the four, or first set of, vertical electrode members 103a-d extend all the way to a side surface of the body 102 where these electrode members are electrically interconnected by the electrically conductive layer 108. Likewise, the three electrode members 105a-c are electrically interconnected by the electrically conductive layer 106 such that the first and second conductive layers serve as respective externally accessible electrical input terminals for establishing electrical coupling to an input AC voltage source.

As illustrated on the vertical cross sectional view of FIG. 1 c), i.e. in a depth direction of the body 102, taken through entire length of the central input section 112 along the L-axis, each of the vertical input electrode members 103a-d comprises a plurality of horizontally extending electrically conductive individual fingers separated in vertical direction by intervening layers of piezoelectric material. Likewise, each of the three vertical input electrode members 105a-c comprises a plurality of horizontally extending electrically conductive individual fingers separated in vertical direction by intervening layers of piezoelectric material. Individual electrodes of the first vertical input electrodes and second vertical input electrodes are deposited pair wise facing each other in an interdigitated layout. In this manner, the plurality of fingers of each electrode member approximate or emulate the functionality of a continuous vertical electrode structure. In the present embodiment of the invention, each electrode of the first and second vertical input electrodes 103a-d, 105a-c, respectively, comprises about 22 individual fingers but may naturally comprises fewer or more fingers such as between 15 and 60 depending on dimensions of the body 102, in particular its thickness, and the utilized manufacturing technology. As illustrated, the piezoelectric material placed in-between consecutive vertical input electrodes is interchangeably polarized in opposite directions as illustrated by the solid arrows therein to ensure that the electrical field in the input section 112 generated by an applied AC input voltage always extend in the longitudinal polarization direction of the piezoelectric material. The dimensions of the elongate piezoelectric body 102 may generally vary widely according to requirements of any particular application.

The present embodiment of the piezoelectric transformer 100 has been fabricated in several different versions with rectangular outlines for experimental test and performance verification.

In a first version, the length (L), width (W) and depth (D) of the elongate piezoelectric body 102 were 20 mm, 10 mm and 2 mm, respectively. Other variants were fabricated with substantially identical width and depth dimensions, but lengths increased to 25 mm and 30 mm, respectively. Table 1 below includes detailed electrical and mechanical data for each of the experimental prototype piezoelectric transformers according to the first version. Each electrode member of the first and second vertical input electrode members 103a-d, 105a-c, respectively, was printed in ceramic layers in width-wise transversal direction to the L-axis of the elongate piezoelectric body 102. After sintering each tape-cast piezoelectric ceramics layer had a thickness of about 33 μm. Each of these ceramic layers has an electrode finger printed thereon which means that the 2 mm thickness or depth (D) of the elongate piezoelectric body 102 comprises about 60 individual vertically aligned fingers. In the present embodiments of the invention, the elongate piezoelectric body 102 is fabricated by piezoelectric ceramics material designated Pz26 available from the manufacturer Ferroperm Piezoceramics NS. The Pz26 material is a hard doped Lead Zirconate Titanate (Pb[ZrxTi1-x]O3 0≦x≦1) (“PZT”) with low loss and well-suited for resonance applications.

TABLE 1
Mechanical and electric key reference or design data for 20 mm, 25 mm
and 30 mm piezoelectric transformer prototypes.

| Half-bridge voltage | Vin | 48 V | 48 V | 48 V | 48 V | 48 V | Volt |
|---|---|---|---|---|---|---|---|
| Body Length | L | 20.00 | 20.00 | 25.00 | 30.00 | 30.00 | mm |
| Body Height | H | 2 | 2 | 2 | 2 | 2 | mm |
| Body Width | W | 10 | 10 | 10 | 10 | 10 | mm |
| Primary volume | | 35.7 | 35.7 | 33.3 | 33.0 | 33.1 | % |
| Primary length | Lp | 7.14 | 7.13 | 8.33 | 9.90 | 9.93 | mm |
| Secondary total length | Ls | 12.86 | 12.87 | 16.67 | 20.10 | 20.07 | mm |
| Volume | V | 0.400 | 0.400 | 0.500 | 0.600 | 0.600 | Cm³ |
| IDE width | IDE | 70 | 70 | 70 | 70 | 70 | μm |
| # primary layers | N_pri | 40 | 40 | 40 | 40 | 40 | |
| Primary layer width | e_pri | 110.25 | 110.00 | 140.00 | 179.25 | 180.00 | μm |
| Electrode shift | | 330.75 | 330.00 | 400.00 | 500.00 | 500.00 | μm |
| Tape thickness | | 33.00 | 33.00 | 33.00 | 33.00 | 33.00 | μm |
| Tape layers | | 60.6 | 61.0 | 61.0 | 60.6 | 61.0 | |
| IDE volume of primary | | 38.2 | 38.3 | 32.8 | 27.6 | 27.5 | % |
| ZVS factor | V_p | 1.49 | | | 1.43 | | |
| Gain | A | 46.89 | | | 44.01 | | |
| Output voltage(RMS) | Vout | 907 | | | 851 | | V |
| Output power | Pout | 4.82 | | | 1.79 | | W |
| Power density | PD | 12.05 | | | 2.98 | | W/cm³ |
| Primary E field | Vpri | 217.7 | | | 133.9 | | V/mm |
| Secondary E field | Vsec | 99.8 | | | 59.9 | | V/mm |

The piezoelectric transformer prototypes are adapted for application of an AC input voltage of 48 V. This voltage may be delivered by a full-bridge transistor driver operating on a 24 Volt DC power supply voltage. The full-bridge transistor driver may for example be based on high-voltage CMOS power transistors where full-bridge output terminals are electrically coupled to the externally accessible input electrodes 108, 106. The target output voltage was about 800 V DC.

For the 20 mm transformer, the length of the input section 112 was 7.14 mm while a combined length of the first and second output sections 114, 116 was 12.86 mm. As indicated in table 1, a ZVS factor of 1.49 or 149% was expected for the 20 mm piezoelectric transformer while a ZVS factor of 1.43 or 143% was expected for the 30 mm transformer.

Each electrode member of the first and second vertical input electrode members 103a-d, 105a-c, respectively, has a nominal or design width of about 70 μm as indicated in Table 1 under “IDE Width”. However, measured data on the experimental 20 mm, 25 m and 30 mm transformer prototypes indicated a typical fabricated width between 45 and 50 μm. The electrode width is measured horizontally along the longitudinal body axis, L-axis. The primary layer width specified in Table 1 is a nominal length of piezoelectric material in-between a facing pair of the first and second vertical input electrodes 103a-d, 105a-c for example between vertical input electrodes 103a and 105a depicted in FIG. 1c) measured horizontally along the longitudinal body axis, L-axis. The nominal primary layer width is 140 μm for the 25 mm experimental transformer. The volume of piezoelectric material caught between the individual horizontal fingers of each electrode member is inactive and does not contribute to the input or primary side effective electromechanical coupling factor, k_{eff P}. Consequently, important performance metrics, in particular k_{eff}_{_{—}}_{P} and, k_{eff}_{_{—}}_{S}, can be further enhanced, compared to the performance of the piezoelectric transformers listed in Table 1 above, by reducing the width of each electrode member of the first and second vertical input electrode members 103a-d, 105a-c, respectively. The width of each of the electrode members could for example be reduced to less than 20 μm or about 10 μm by existing fabrication technologies.

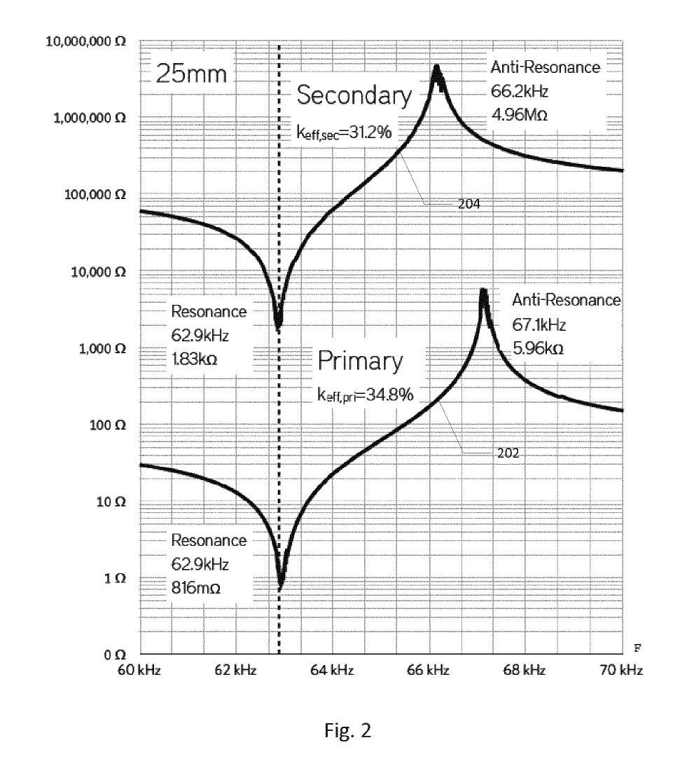

FIG. 2 shows a measured input/primary side impedance curve 202 of an experimental prototype piezoelectric transformer in accordance with a first version of the first embodiment of the invention. The impedance function 202 or curve was obtained at the first and second input electrodes of the above-described 25 mm prototype piezoelectric transformer in accordance with the first version with shorted first and second output electrodes. The first and second input electrodes are electrically coupled to the externally accessible electrically conductive layers 108, 106 as depicted on FIG. 1 while the first and second output electrodes correspond to the output electrodes 120, 122, respectively, as depicted on FIG. 1 above.

The output/secondary side impedance curve 204 or function was obtained at the output electrodes of the above-described experimental 25 mm prototype piezoelectric transformer with shorted input electrodes. The measurements were made by an HP4194A Impedance/Gain-Phase analyzer. The input side impedance function or curve 202 allows direct determination of the primary side effective electromechanical coupling factor, k_{eff}_{_{—}}_{P}, by reading a value of fₐₙₜᵢ_{_{—}}ᵣₑₛ_{_{—}}ₚ=67.1 kHz (the maximum magnitude of the impedance function) and a value of fᵣₑₛ_{_{—}}ₚ=62.9 kHz (the minimum magnitude of the impedance function) and finally applying equation (1):

$${k}_{eff\_P} = \sqrt{1 - \frac{{f}_{res\_p}^{2}}{{f}_{anti - res\_p}^{2}}}$$

which leads to a numerical value of k_{eff}_{_{—}}_{P}=0.348. Likewise, the secondary side impedance curve 204 allows direct determination of the secondary side effective electromechanical coupling factor, k_{eff}_{_{—}}_{S} by reading a value of fₐₙₜᵢ_{_{—}}ᵣₑₛ_{_{—}}ₛ=66.2 kHz (the maximum magnitude of the impedance function) and fᵣₑₛ_{_{—}}ₛ=62.9 kHz (the minimum magnitude of the impedance function 204) and applying equation (2):

$${k}_{eff\_S} = \sqrt{1 - \frac{{f}_{res\_s}^{2}}{{f}_{anti - res\_s}^{2}}}$$

which leads to a numerical value of k_{eff}_{_{—}}_{S}=0.312 or 31.2%.

Finally, applying equation (3) above to these values leads to a ZVS factor of about 110% for the present experimental 25 mm piezoelectric transformer.

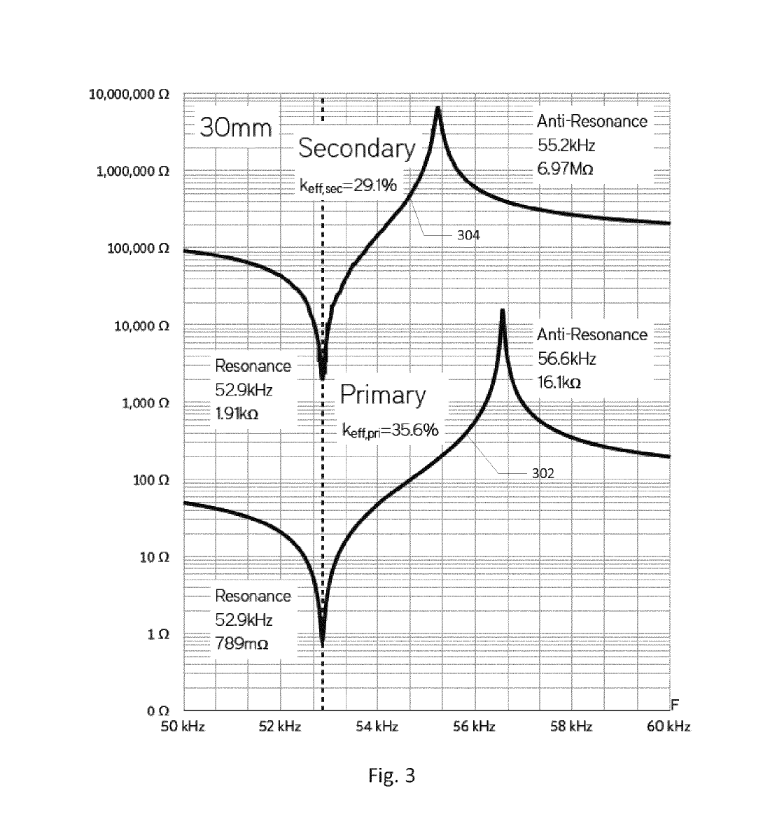

FIG. 3 shows a measured input/primary side impedance curve 302 of an experimental piezoelectric transformer with a length of 30 mm, but which otherwise is similar to the above-discussed 25 mm experimental piezoelectric transformer. The differences in mechanical dimensions between the two experimental piezoelectric transformers are outlined in Table 1 above. The input side impedance function 302 or curve was obtained at an input electrode of the 30 mm prototype piezoelectric transformer with shorted first and second output electrodes employing the same methodology as mentioned above for the 25 mm prototype piezoelectric transformer. The output/secondary side impedance curve 304 or function was obtained at the output electrodes of the above-described 30 mm prototype piezoelectric transformer with shorted input electrodes. The measured impedance function or curve 302 allows direct determination of the primary side effective electromechanical coupling factor, k_{eff}_{_{—}}_{P} by reading a value of fₐₙₜᵢ_{_{—}}ᵣₑₛ_{_{—}}ₚ=56.6 kHz (the maximum magnitude of the impedance function) and a value of fᵣₑₛ_{_{—}}ₚ=52.9 kHz (the minimum magnitude of the impedance function) and proceeding as above which leads to a numerical value of K_{eff}_{_{—}}_{P}=0.356. Likewise, the impedance curve 304 allows direct determination of the secondary side effective electromechanical coupling factor, k_{eff}_{_{—}}_{S} by reading a value of fₐₙₜᵢ_{_{—}}ᵣₑₛ_{_{—}}ₛ=55.2 kHz (the maximum magnitude of the impedance function) and fᵣₑₛ_{_{—}}ₛ=52.9 kHz (the minimum magnitude of the secondary side or output impedance function 304) and proceeding as above which leads to a numerical value of k_{eff}_{_{—}}_{S}=0.291 or 29.1%. Consequently, the value of k_{eff}_{_{—}}_{P} is about 22% larger than the value of k_{eff}_{_{—}}_{S}. Applying equation (1) above to these values furthermore leads to a ZVS factor of about 136% for the present experimental 30 mm piezoelectric transformer.

It is worthwhile to notice that the difference between the measured ZVS factors of the 25 mm and 30 mm experimental prototypes (i.e. 110% versus 136%) because this parameter would ideally be substantially identical when only the length of the piezoelectric body is varied as in the present case. However, the measured difference is largely caused by the fabricated and finite width of 45-50 μm, i.e. the IDE width as expressed in Table 1, of each electrode member. The piezoelectric material stuck in-between individual fingers of each electrode member (103a and 105a on FIG. 1c)) is inactive and does not contribute to the primary side effective electromechanical coupling factor, k_{eff}_{_{—}}_{P} as explained above. Because the 25 mm and 30 mm prototype transformers use the same electrode dimensions and number of electrodes, the relative amount of inactive piezoelectric material in the input section of the 25 mm transformer is higher than in the input section of the 30 mm transformer because of the larger dimensions of the input section of the latter transformer.

The skilled person will appreciate that ZVS factors above the demonstrated 1.36 or 136% are readily obtainable by increasing the length of the elongate piezoelectric body and/or decreasing the IDE width of each electrode member.

Experimental prototype PTs according to a second embodiment of the piezoelectric transformer 100 has been fabricated in two different versions with rectangular outlines for additional experimental test and performance verification. In a first version, the length (L), width (W) and depth (D) of the elongate piezoelectric body 102 were 27.3 mm, 10 mm and 2 mm, respectively. The length of the central input section was 9.9 mm build by 40 IDE layers. The elongate piezoelectric body 102 was fabricated in the NCE46 hard doped piezoelectric ceramics material. The second version was identical expected for a depth (D) of 1 mm.

Table 2 and table 3 below show the measured data for the primary side and second side effective electromechanical coupling factors k_{eff}_{_{—}}_{P} and k_{eff}_{_{—}}_{S} together with the computed corresponding ZVS factors. Evidently, the primary side effective electromechanical coupling factor is markedly larger than the second side effective electromechanical coupling factor in both variants. The ZVS factors are also well above 100%.

TABLE 2
Measured primary side and second side effective electromechanical
coupling factors for piezoelectric transformer prototypes according
to the second embodiment.

| Sample | k_{eff.P} | k_{eff.S} |
|---|---|---|
| IDE27mm1 | 40.6% | 35.6% |
| IDE27mm2 | 40.2% | 36.0% |

TABLE 3
Computed ZVS factors for the piezoelectric transformer prototypes
according to the second embodiment

| Sample | | ZVS |
|---|---|---|
| IDE27 mm1 | $ZVS = \frac{35.6 {\%}^{- 2} - 1}{40.6 {\%}^{- 2} - 1} 0.882$ | 119% |
| IDE27 mm2 | $ZVS = \frac{35.0 {\%}^{- 2} - 1}{40.2 {\%}^{- 2} - 1} 0.882$ | 113% |

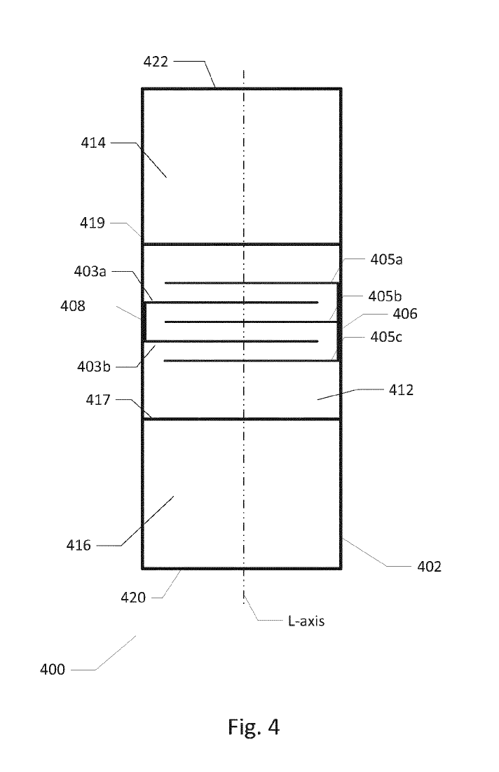

FIG. 4 is a schematic top side view of a multi-piece piezoelectric transformer 400 in accordance with a third embodiment of the invention. The present multi-piece piezoelectric transformer 400 comprises an elongate piezoelectric ceramic body 402 comprising three separate piezoelectric ceramics structures 412, 416, 414. A central input section 412 is made as true k₃₃₃ multilayer structure while first and second output or secondary 414, 416 are formed as unitary bulk layers. The central input section 412 is manufactured by stacking adding about 48 thin layers of ceramics in a lengthwise direction (along the depicted L-axis) of the input section 412 but the skilled person will understand that fewer or more layers could be utilized depending on the target dimensions of the input section 412 and manufacturing equipment. The central input section 412 is firmly attached or bonded to the first secondary section 414 at a first bonding layer 419 disposed between opposing edges of ceramic sections 412, 414. Likewise, an opposing edge of the central input section 412 is firmly attached or bonded to the second output section 416 at a second bonding layer 417 disposed between opposing edges of ceramic sections 412, 416. The separate ceramics structures 412, 416, 414 are preferably bonded together by a Low temperature Co-fired Ceramic (LTCC) material.

Each of the central input section 412 and secondary sections 412, 414 is manufactured in the previously discussed hard doped piezoceramic material NCE46. The length (L), width (W) and depth (D) dimensions of the elongate piezoelectric body are 10.7 mm, 6.4 mm and 6.4 mm, respectively. The length of central input section 412 is about 3.5 mm such that the volumetric occupation of the central input section amounts to about 33% of the elongate piezoelectric body 402. The central input section 412 comprises a first vertical input electrode comprising two individual first electrode members 403a-b. The two individual first electrode members 403a-b are terminated electrically in an externally accessible electrically conductive layer 408 arranged at a proximate exterior surface of the elongate piezoelectric ceramic body 402. A second vertical input electrode comprises three individual second electrode members 405a-c terminated in a shared externally accessible electrically conductive layer 406 arranged at an opposing exterior surface. By application of an AC input voltage between the electrically conductive layers 408, 406, coupled to the first and second sets of input electrode member, respectively, electrical fields are applied to the central input section 412 along its polarization direction as described in connection with FIG. 1 above.

The first and second output sections 414, 416 are polarized in a direction substantially parallel to a longitudinal body axis, L-axis, of the body 402. The first output section 414 comprises a first output electrode 422 arranged at an end surface thereof. Likewise, the second output section 416 comprises a second output electrode 420 deposited on an end surface of the second output section arranged oppositely lengthwise to the end surface carrying the first output electrode 422. Each of the first and second output electrodes 422, 420, respectively, preferably comprises a thin layer of metallic material or other electrically conductive material. Each of the first and second output electrodes 422, 420, respectively, may be fastened or arranged on the end surface of the output section in question by printing techniques or similar methods of depositing metallic material on ceramic surfaces. Alternatively, the first and second output electrodes may be fastened to the end surface in question by welding, gluing or soldering a thin slab of electrode material to the end surface. In both situations, a length (along the L-axis) of each of the first and second output electrodes 422, 420, respectively, may be less than 1 mm, preferably less than 100 μm, or even more preferably less than 20 μm.

Table 4 below shows the measured data for the primary side and second side effective electromechanical coupling factors k_{eff}_{_{—}}_{P} and k_{eff}_{_{—}}_{S} of the prototype multi-piece piezoelectric transformer 400. These correspond to a ZVS factor of 170%. Evidently, the primary side effective electromechanical coupling factor has the desired and advantageous markedly higher value than the second side effective electromechanical coupling factor.

TABLE 4
Measured primary side and second side effective
electromechanical coupling factors for piezoelectric
transformer prototype according to the third embodiment.

| Sample | k_{eff.P} | k_{eff.S} |
|---|---|---|
| 1 + 1 + 1 #2 | 44.8% | 31.9% |

The above measurement results demonstrate that very high ZVS factors are readily obtainable by utilizing a true 333 thickness structure or build-up of the central input section of the elongate piezoelectric ceramic body. The true 333 thickness structure eliminates the above-discussed inactive area/volume of piezoceramic material caught between the individual electrically conductive fingers of the IDE electrodes. The true 333 thickness structure is therefore capable of providing higher power conversion efficiency and/or power density of the piezoelectric transformer because the primary side effective electromechanical coupling factor k_{eff}_{_{—}}_{P} is not degraded by the inactive area/volume of piezoceramic material. Clearly, not only the central input section, but the entire elongate piezoelectric ceramic body may be manufactured as a true 333 thickness structure by stacking or adding the thin ceramics layers in the lengthwise direction of the elongate piezoelectric ceramic body 402. The above specified length of 10.7 mm of the elongate piezoelectric ceramic body 402 may be achieved by stacking about 300-400 individual thin ceramics layers.

1. A piezoelectric transformer comprising:
an elongate piezoelectric ceramic body adapted to operate in fundamental thickness mode, comprising:
a central input section polarized in a direction substantially parallel to a longitudinal body axis of the elongate piezoelectric ceramic body,
said input section comprising at a first and a second input electrode for applying an electrical field to the central input section along its polarization direction,
a first output section polarized in a direction substantially parallel to the longitudinal body axis,
the first output section being arranged in abutment to the central input section at a first connection surface and comprising a first output electrode,
a second output section polarized in a direction substantially parallel to the longitudinal body axis,
the second output section being arranged in abutment to the central input section at a second connection surface, arranged oppositely to the first connection surface, and comprising a second output electrode; wherein
a primary side effective electromechanical coupling factor, k_{eff}_{_{—}}_{P}, is larger than a secondary side effective electromechanical coupling factor, k_{eff}_{_{—}}_{S},
in which:
$$\begin{matrix}{k}_{eff\_P} = \sqrt{1 - \frac{{f}_{res\_p}^{2}}{{f}_{anti - res\_p}^{2}}} \\ {k}_{eff\_S} = \sqrt{1 - \frac{{f}_{res\_s}^{2}}{{f}_{anti - res\_s}^{2}}}\end{matrix}$$
fᵣₑₛ_{_{—}}ₚ=resonance frequency and frequency of a minimum magnitude of an impedance function at the input electrodes of the piezoelectric transformer with shorted output electrodes,
fₐₙₜᵢ₋ᵣₑₛ_{_{—}}ₚ=anti-resonance frequency and frequency of a maximum magnitude of the impedance function at the input electrodes of the piezoelectric transformer with shorted output electrodes,
fᵣₑₛ_{_{—}}ₛ=resonance frequency and frequency of a minimum magnitude of the impedance function at the output electrodes of the piezoelectric transformer with shorted input electrodes,
fₐₙₜᵢ₋ᵣₑₛ_{_{—}}ₛ=anti-resonance frequency and frequency of a maximum magnitude of the impedance function at the output electrodes of the piezoelectric transformer with shorted input electrodes.

2. A piezoelectric transformer according to claim 1, wherein the primary side effective electromechanical coupling factor, k_{eff}_{_{—}}_{P}, is larger than 0.3 or 30%, or larger than 0.35 or 35%, or larger than 0.4 or 40%, or larger than 0.5 or 50% or 0.6 or 60%.

3. A piezoelectric transformer according to claim 2, wherein the central input section comprises a hard doped piezoceramic material exhibiting a k₃₃ electromechanical coupling factor above 0.60, the piezoceramic material including NCE40, NCE41, Pz26 or NCE46.

4. A piezoelectric transformer according to claim 2 or 3, wherein the primary side effective electromechanical coupling factor, k_{eff}_{_{—}}_{P}, is at least 10% larger than the secondary side effective electromechanical coupling factor, k_{eff}_{_{—}}_{S}.

5. A piezoelectric transformer according to claim 4, wherein the primary side effective electromechanical coupling factor, k_{eff}_{_{—}}_{P}, is between 12% and 80% larger than the secondary side effective electromechanical coupling factor, k_{eff}_{_{—}}_{S}.

6. A piezoelectric transformer according to claim 1, wherein the elongate piezoelectric ceramic body is shaped and sized to provide a zero-voltage switching factor (ZVS factor) larger than 100%, or larger than 120%, or larger than 150% or 200%;
in which the ZVS factor is determined at a matched load condition as:
$$Z V S = \frac{( {k}_{eff\_S}^{- 2} ) - 1}{( {k}_{eff\_P}^{- 2} ) - 1} 0.882$$

7. A piezoelectric transformer according to claim 5, having ZVS factor larger than 125%;
wherein a volume of the central input section occupies less than 50% of a volume of the elongate piezoelectric ceramic body.

8. A piezoelectric transformer according to claim 1, wherein a length of the elongate piezoelectric ceramic body is larger than any other dimension thereof, wherein the dimension includes a thickness, width or diameter of the elongate piezoelectric ceramic body.

9. A piezoelectric transformer according to claim 8, wherein the length of the elongate piezoelectric ceramic body is at least two times larger than any other dimension thereof.

10. A piezoelectric transformer according to claim 1, wherein the elongate piezoelectric ceramic body is formed as a single unitarily machined body of anisotropic piezoelectric compound without any junctions or joints at the first and second connection surfaces.

11. A piezoelectric transformer according to claim 1, wherein the elongate piezoelectric ceramic body is formed by between 2 and 5 separate piezoelectric ceramics structures bonded to each other at one or more respective edge surfaces.

12. A piezoelectric transformer according to claim 10, wherein the central input section comprises a true 333 thickness structure fabricated by stacking or adding a plurality of ceramics layers in a lengthwise direction of the central input section.

13. A piezoelectric transformer according to claim 1, wherein the input section comprises a first vertically extending input electrode and a second vertically extending input electrode;
the first and second vertically extending input electrodes being separated by an intermediate section of piezoelectric material in direction of the longitudinal body axis.

14. A piezoelectric transformer according to claim 13, wherein:
the first vertically extending input electrode comprises a plurality of first electrode members distributed along the longitudinal body axis and separated by intermediate sections of piezoelectric material; and
the second vertically extending input electrode comprises a plurality of second electrode members distributed along the longitudinal body axis and separated by intermediate sections of piezoelectric material;

15. A piezoelectric transformer according to claim 12, wherein:
the first vertically extending input electrode or each of the first electrode members comprises respective set(s) of electrically conductive horizontal fingers aligned vertically above each other and separated by intervening layers of the piezoelectric material; and
the second vertically extending input electrode or each of the second electrode members comprises respective set(s) of electrically conductive horizontal fingers aligned vertically above each other and separated by intervening layers of the piezoelectric material;

16. A piezoelectric transformer according to claim 13, wherein:
the first vertically extending input electrode or each of the first electrode members is/are electrically connected to a first electrically conductive layer arranged at a first exterior surface of the elongate piezoelectric ceramic body; and
the second vertically extending input electrode or each of the second electrode members is/are electrically connected to a second electrically conductive layer arranged at a second exterior surface of the elongate piezoelectric ceramic body.

17. A piezoelectric transformer according to claim 14, wherein:
a distance, along the longitudinal body axis, between at individual electrode members of the first electrode members lies between 200 μm and 2 mm, or between 400 μm and 1 mm; and
a distance, along the longitudinal body axis, between at individual electrode members of the second electrode members lies between 200 μm and 2 mm, or between 400 μm and 1 mm.

18. A piezoelectric transformer according to claim 1, wherein the first output electrode is arranged (printed or deposited metallic layer) on an end surface of the first output section and the second output electrode arranged on an end surface of the second output section;
wherein a length of each of the first and second output electrodes is less than 1 mm, or less than 100 μm, or preferably less than 20 μm.

19. A piezoelectric transformer according to claim 1, wherein the first output electrode is arranged on an end surface of the first output section and the second output electrode arranged on an end surface of the second output section;
wherein a length of each of the first and second output electrodes is significantly less than a length of the first and second output sections, or less than 50%, or less than 10%, or less than 1%, of the length.

20. A resonant piezoelectric power converter comprising a piezoelectric transformer according to claim 1, comprising:
a transistor driver with an output electrically coupled to the at least two input electrodes of the input section and adapted to supplying an input AC voltage of predetermined amplitude and frequency characteristics to the at least two input electrodes,
a load impedance electrically coupled to the first and second output sections of the piezoelectric transformer for receipt of a transformed AC voltage.

21. A resonant piezoelectric power converter according to claim 20, wherein an excitation frequency of the input AC voltage is situated between 5 and 10% above a fundamental resonance frequency of the elongate piezoelectric ceramic body.
